(19) United States
(12) Patent Application Publication
(10) Pub. No.: US 2007/0009650 A1
(43) Pub. Date: Jan. 11, 2007

(54) Paste dispenser and method of controlling the same

(76) Inventors: Yong-ju Cho, Paju-si (KR); Jae-uk Lee, Gumi-si (KR); Yun-hoi Kim, Gumi-si (KR); Seo-ho Son, Gyeongsan-si (KR)

Correspondence Address: HARNESS, DICKEY & PIERCE, P.L.C., P.O. BOX 8910, RESTON, VA, 20195, US

(21) Appl. No.: 11/476,794

(22) Filed: Jun. 29, 2006

(30) Foreign Application Priority Data
Jul. 8, 2005 (KR) 10-2005-0061735
Jul. 8, 2005 (KR) 10-2005-0061736

(51) Int. Cl. C23C 16/52; B05C 5/00; B05B 3/00

(52) U.S. Cl. 427/8; 118/305; 118/300; 427/424; 118/679; 118/323

(57) ABSTRACT

A paste dispenser and a method of controlling the same are disclosed. The paste dispenser includes a dispensing head having a nozzle for dispensing paste mounted thereon, and a stage having a substrate mounted thereon and moving relative to the dispensing head, in which the substrate mounted on the stage is moved without rotating the stage to form a paste pattern. The method of controlling the paste dispenser includes putting a substrate on a stage, acquiring position information of the substrate on the stage, and setting a dispensing position of a nozzle by moving a dispensing head having the nozzle mounted thereon without rotating the stage.

### CROSS-REFERENCE TO RELATED APPLICATION

This application claims the priorities of Korean Patent Application Nos. 2005-0061735 and 2005-0061736, filed on Jul. 8, 2005, in the Korean Intellectual Property Office, the disclosures of which are incorporated herein in their entireties by reference.

### BACKGROUND OF THE INVENTION

1. Field of the Invention

The present invention relates to a paste dispenser and a method of controlling the same, and particularly, to a paste dispenser for forming a paste pattern rapidly and accurately with reduced vibration and a method of controlling the same.

2. Discussion of the Related Art

A paste dispenser is designed to dispense various types of paste, such as an adhesive paste and a sealing paste, on a substrate in a predetermined pattern.

The paste dispenser comprises a stage on which a substrate is mounted, a head unit having a nozzle for dispensing a paste on the substrate, a column on which the head unit is mounted, and a controller that controls the movement of the column and the head unit. The head unit includes a paste container containing the paste therein. The paste container is connected to the nozzle.

The paste dispenser forms a predetermined pattern on the substrate while changing a relative distance between the substrate and the nozzle. That is, when the paste is dispensed, the substrate moves in a predetermined direction and the head unit mounted on the column moves in a direction perpendicular to the moving direction of the substrate. Thereinafter, such a movement between the substrate and the nozzle is referred to as a relative movement between the substrate and the nozzle.

FIG. 1 illustrates a cross-sectional view of a stage driver included in a paste dispenser. FIG. 2 illustrates a perspective view of a stage driver included in a paste dispenser. FIG. 3A illustrates a diagram showing a substrate which is initially put on a stage included in a paste dispenser. FIG. 3B illustrates a diagram showing a substrate which is placed in a right position by rotating a stage on which the substrate is mounted.

A stage driver included in a conventional paste dispenser and a step of setting a position of a substrate by the use of the stage driver will be described in detail with reference to FIGS. 1 to 3B.

The paste dispenser includes a frame 10, which is provided at a lower part of the paste dispenser, and a stage driver 7, which is provided to drive a stage 40. The stage driver 7 includes a Y-axis stage carrier 3 for moving the stage 40 along the Y-axis. The stage 40 is provided on a Y-axis table 5. As the Y-axis table 5 is moved by the Y-axis stage carrier 3, the stage 40 is moved in the Y-axis direction.

A θ-axis driver 1 is provided on the Y-axis stage carrier 3 to move the stage along the θ-axis. The θ-axis driver 1 is provided between the stage 40 and the Y-axis table 5. The substrate is mounted on the stage 40.

As shown in FIG. 2, the θ-axis driver 1 includes a rotating guide 1a and a θ-axis motor 1b to rotate the stage 40. As the θ-axis motor 1b rotates the rotating guide 1a, the stage 40 placed on the rotating guide 1a is rotated.

A step of placing a substrate at a right position before forming a paste pattern on the substrate will be described.

An operator puts the substrate 200 on the stage 40 by means of a transporter. As shown in FIG. 3A, when the substrate is put on the stage by the transporter, a Y-axis direction, in which the substrate is moved, will not generally run parallel with a Y′-axis direction, in which a paste pattern is to be formed on the substrate. In other words, an X-axis direction, in which a dispensing head is moved, and a X′-axis direction, in which the paste pattern is to be formed on the substrate, are deviated from each other by a predetermined angle θ.

Thus, the position of the substrate needs to be corrected so that the X-axis direction and the X′-axis direction can be matched with each other before forming the paste pattern.

The paste dispenser rotates the stage by the angle θ by means of the θ-axis driver to correct the position of the substrate. FIG. 3B illustrates the substrate that is placed in a right position.

Subsequently, the paste dispenser moves a nozzle to a dispensing start point, and forms the paste pattern on the substrate while moving the substrate and the nozzle.

However, the paste dispenser and the method of controlling the same have the following problems.

The paste dispenser includes the Y-axis stage carrier and the θ-axis driver and forms the paste pattern while moving the stage along the Y-axis. In this case, when a driving force of the Y-axis stage carrier is transmitted to the stage, vibration occurs due to the θ-axis driver that is interposed between the Y-axis stage carrier and the stage, causing the stage to vibrate. Further, the vibration of the stage causes the substrate to vibrate, resulting in an unsatisfactory paste pattern.

In addition, since the paste dispenser includes the Y-axis stage carrier and the θ-axis driver and forms the paste pattern while moving the stage along the Y-axis, a load imposed on the Y-axis stage carrier increases due to the θ-axis driver. In other words, a time interval between the time when a control signal for moving the stage is applied and the time when the stage is actually moved increases due to the load imposed by the θ-axis driver on the Y-axis stage carrier. Thus, the paste dispenser cannot dispense an accurate amount of paste at an accurate position.

Further, the paste dispenser requires a step of rotating the stage having the substrate put thereon in the θ-axis direction to move the substrate in a right position before forming the paste pattern. Accordingly, it takes long time for the paste dispenser to set the position of the substrate on the stage.

### SUMMARY OF THE INVENTION

The present invention is directed to a paste dispenser that substantially overcomes the above-mentioned limitations and disadvantages of the related art, and a method of controlling the same.

An object of the present invention is to provide a paste dispenser that forms a paste pattern rapidly and accurately with reduced vibration, and a method of controlling the same.

Another object of the present invention is to provide a paste dispenser that reduces a time interval between the time when a control signal for moving the stage is applied and the time when the stage is actually moved, thus dispensing an accurate amount of paste at an accurate position, and a method of controlling the same.

A further object of the present invention is to provide a paste dispenser that reduces the time required for setting a position of a substrate on a stage, and a method of controlling the same.

Other advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

According to an aspect of the present invention, there is provided a paste dispenser including: a dispensing head having a nozzle for dispensing paste mounted thereon; and a stage having a substrate mounted thereon and moving relative to the dispensing head, in which the substrate mounted on the stage is moved without rotating the stage to form a paste pattern.

According to another aspect of the present invention, there is provided a paste dispenser including: a stage having a substrate mounted thereon; a dispensing head having mounted thereon a nozzle for dispensing paste on the substrate; and a position sensor acquiring position information of the substrate on the stage, in which the dispensing head is moved without rotating the stage to set a position of the nozzle.

According to another aspect of the present invention, there is provided a paste dispenser including: a dispensing head having a nozzle for dispensing paste mounted thereon; a column having the dispensing head mounted thereon and stopping operating when the paste is dispensed; and a stage moving in a direction perpendicular to a movement direction of the dispensing head without rotating about the column.

According to another aspect of the present invention, there is provided a method of controlling a paste dispenser, the method including: putting a substrate on a stage; acquiring position information of the substrate on the stage; and setting a dispensing position of a nozzle by moving a dispensing head having the nozzle mounted thereon without rotating the stage.

According to another aspect of the present invention, there is provided a method of controlling a paste dispenser, the method including putting a substrate on a stage; inputting position data of a paste pattern formed on the substrate; acquiring position information of the substrate on the stage; and correcting initial position data of the paste pattern on the basis of the position information of the substrate.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a cross-sectional view of a stage driver included in a conventional paste dispenser;

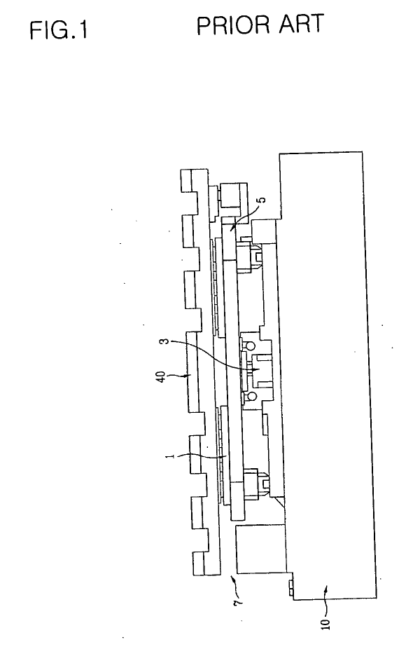

FIG. 2 illustrates a perspective view of a stage driver included in a conventional paste dispenser;

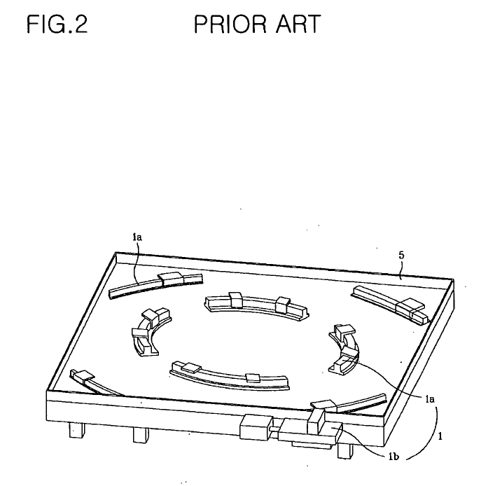

FIG. 3A illustrates a diagram showing a substrate which is put on a stage included in a conventional paste dispenser;

FIG. 3B illustrates a diagram showing a substrate which is placed in a right position in a conventional paste dispenser;

FIG. 4 illustrates a perspective view showing the structure of a paste dispenser according to the present invention;

FIG. 5 illustrates a cross-sectional view of a stage driver included in a paste dispenser according to the present invention;

FIG. 6 illustrates a perspective view showing an embodiment of a head unit included in a paste dispenser according to the present invention;

FIG. 7 illustrates a block diagram showing a configuration for controlling a paste dispenser according to the present invention;

FIG. 8 illustrates a diagram showing a right dispensing position which is set by moving a nozzle mounted on a column according to the present invention; and

FIG. 9 illustrates a flow chart showing a method of controlling a paste dispenser according to the present invention.

### DETAILED DESCRIPTION OF THE INVENTION

Reference will now be made in detail to the preferred embodiments of the present invention, examples of which are illustrated in the accompanying drawings.

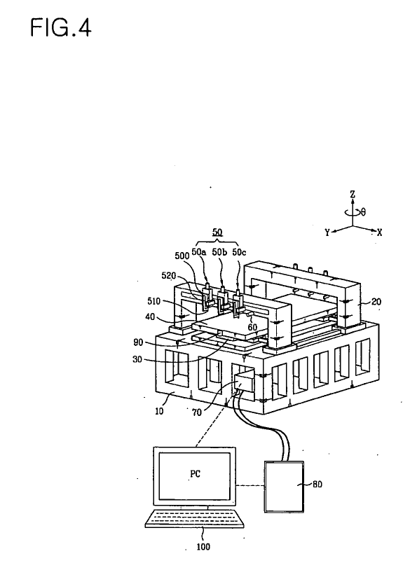

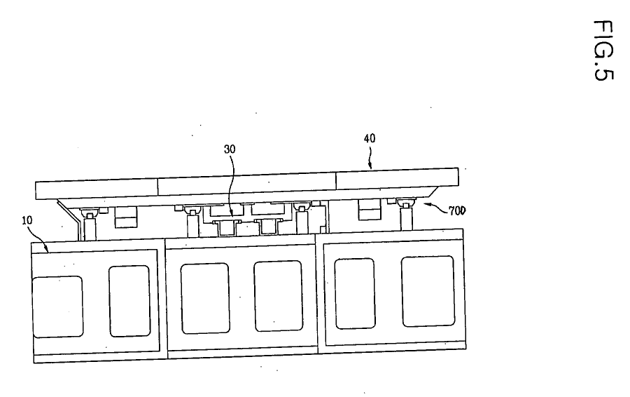

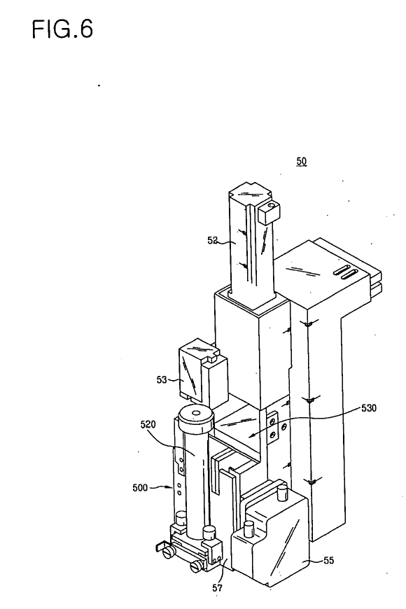

FIG. 4 illustrates a perspective view showing a preferred embodiment of a paste dispenser according to the present invention. FIG. 5 illustrates a cross-sectional view of a stage driver according to the present invention. FIG. 6 illustrates a perspective view showing a preferred embodiment of a head unit according to the present invention.

Referring to FIGS. 4 to 6, the structure of the paste dispenser according to the present invention will be described in detail.

A stage driver 700 is mounted on a frame 10 to move a stage 40 on which a substrate is put. A Y-axis stage carrier 30 is mounted on the stage driver 700 to move the stage 40 in the Y-axis direction. The stage 40 on which the substrate is put is mounted on the Y-axis stage carrier 30.

That is, in the present embodiment, since a θ-axis driver for moving the stage in a θ-axis direction is not provided, the stage 40 does not rotate and the substrate is moved while it is mounted on the stage.

At least one column 20 is provided on the frame 10 and is moved in the Y-axis.

A plurality of head units 50 is mounted on the column 20. Each of the head units 50 is movable in the X-axis direction. Forming a plurality of paste patterns on the substrate with the plurality of head units 50 may reduce the process time.

The head unit 20 includes a dispensing head 500 equipped with a nozzle 510 dispensing paste, and a Y-axis dispensing head carrier 530 for moving the dispensing head 500 in the Y-axis direction. The Y-axis dispensing head carrier 530 moves the dispensing head 500 in the Y-axis to set a position of the nozzle 510 before the paste is dispensed.

The Y-axis dispensing head carrier 530 includes a servomotor (not shown) and a motor shaft (not shown) that is driven by the servomotor. The servomotor rotates the motor shaft, and the dispensing head 500 connected to the motor shaft is therefore moved in the Y-axis.

A paste container 520 for containing paste is mounted on the dispensing head 500 included in the head unit 50. The head unit 50 includes a Z-axis motor 52 for moving the nozzle 510 in the Z-axis direction.

The head unit 50 may further include a Z-axis fine adjustment motor 53 (thereinafter referred to as ‘ZZ-axis motor’) for finely adjusting the height of the head unit 50, thereby accurately adjusting the distance between the nozzle and the substrate after putting the substrate on the stage.

In addition, the head unit 50 includes a distance sensor 57 for measuring a relative distance between the nozzle and the substrate when paste is dispensed, and a sectional area sensor 55 for measuring the sectional area of the paste pattern after the paste pattern is formed.

Measuring units 90 are provided on the front and rear sides of the stage 40 to set a position of a replacement nozzle. The measuring unit 90 may be an image sensing device such as a camera.

The paste controller includes a controller 70, which is connected to an input/output unit 80 for inputting/outputting operation information required for operating the paste dispenser. The controller 70 may directly receive position data concerning the paste pattern from the input/output unit 80 or a personal computer 100.

Position sensors 60 are provided on the column 20 to obtain position information of the substrate on the stage. That is, the position sensors 60 are provided on both ends of the column 20. The position sensor 60 serves to check whether or not the substrate put on the stage is located at a position at which the paste pattern is to be dispensed.

A process in which the paste dispenser acquires the position of the substrate by means of the position sensor will be described.

After a substrate is put on the stage, the paste dispenser moves the column having the position sensor 60 mounted thereon to a predetermined position. The predetermined position is previously input to the controller of the paste dispenser.

The position sensor 60 detects alignment marks on the substrate. A plurality of alignment marks (not shown) is indicated on the substrate to identify the position of the substrate.

The controller of the paste dispenser calculates a change in position of the substrate that corresponds to a deviation of the substrate from a reference position, at which the substrate is to be initially located, on the basis of position information obtained from the position sensor.

The change in position includes an angle formed between the X-axis direction in which the dispensing head moves and the X′-axis direction in which the paste pattern is to be dispensed, and a change in position between a reference point of the paste pattern which is initially input and a reference point of the paste pattern to be dispensed on the substrate.

In case the angle formed between the X-axis direction and the X′-axis direction is 0° and the reference point initially inputted is equal to the reference point of the paste pattern to be dispensed, the paste dispenser determines that the substrate is located at the reference position.

The position sensor may be mounted on the head unit rather than the column. The position sensor may be an image sensing device, such as a camera, that can measure the position of the substrate on the stage. Any sensing device measuring a deviation of the substrate on the stage may be used as the position sensor.

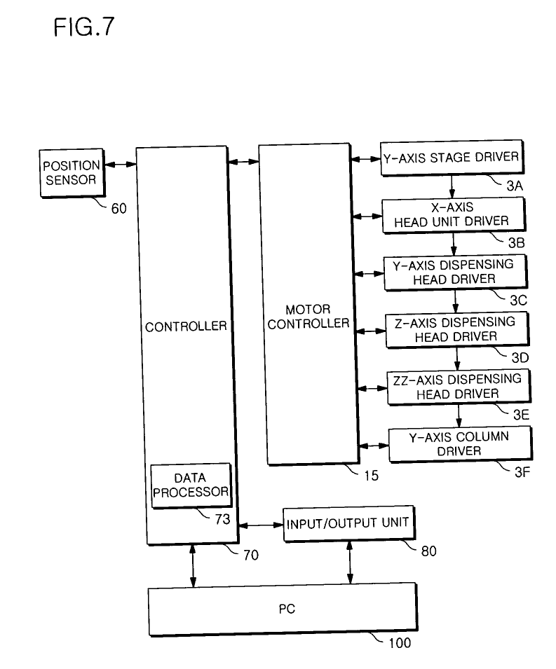

FIG. 7 illustrates a block diagram showing a configuration for controlling the paste dispenser according to the present invention.

The controller 7 including a central processing unit is connected to each of a motor controller 15, an input/output unit 80, and a personal computer 100. The personal computer 100 may be connected to the input/output unit 80 instead of being directly connected to the controller 70.

The motor controller 15 is connected to a Y-axis stage driver 3a that controls the Y-axis movement of a stage. The motor controller 15 is connected to an X-axis head unit driver 3b that moves a head unit in the X-axis. When a plurality of head units is provided, a plurality of X-axis head unit drivers is provided to move each of the head units in the X-axis.

In addition, the motor controller is connected to each of a Y-axis dispensing head driver 3c, a Z-axis dispensing head driver 3d, and a ZZ-axis dispensing head driver 3e to move a nozzle in the Y-axis, Z-axis, and ZZ-axis directions, respectively. Further, the motor controller is connected to a Y-axis column driver 3f that moves a column in the Y-axis.

The Y-axis dispensing head driver 3c is controlled by the motor controller 15. The motor controller 15 is connected to the controller 70. The controller 70 is connected to the position sensor 60.

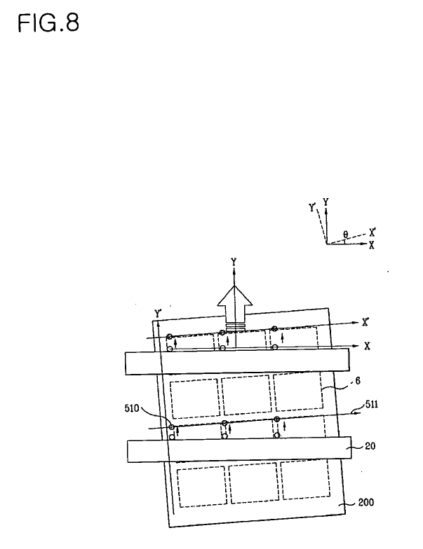

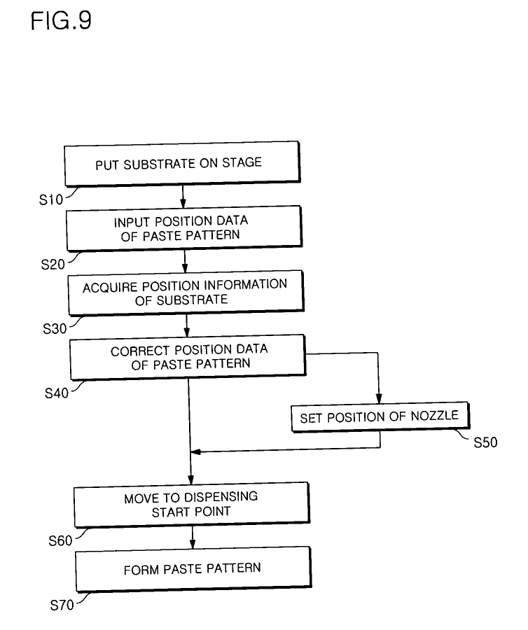

FIG. 8 illustrates a diagram showing a right dispensing position which is set by moving a nozzle mounted on a column according to the present invention. FIG. 9 illustrates a flow chart showing a method of controlling a paste dispenser according to the present invention.

A method of controlling the paste dispenser according to the present invention will be described in detail with reference to FIGS. 8 and 9.

An operator puts on a stage a substrate on which a paste pattern is to be formed (S10). The operator sets a dispensing condition required for forming the paste pattern. The dispensing condition includes a speed (thereinafter referred to as ‘dispensing speed’) at which a nozzle moves in a direction parallel to the substrate on which the paste is dispensed, a height (thereinafter referred to as ‘dispensing height’) at which the nozzle is located vertically from the substrate on which the paste is dispensed, and a pressure (thereinafter referred to as ‘dispensing pressure’) which is applied to a paste container to dispense the paste.

The operator inputs position data concerning the paste pattern to the paste dispenser (S20). It should be understood that the substrate may be mounted on the stage after inputting the dispensing condition and the position data concerning the paste pattern.

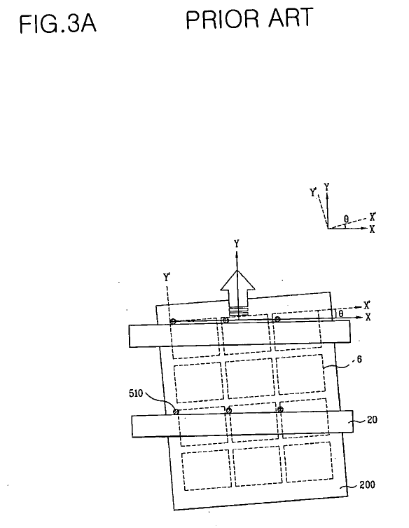

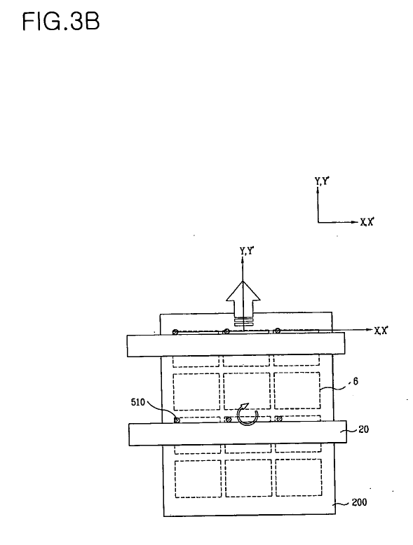

As shown in FIG. 3A, when a substrate is mounted on a stage by means of a transporter, the X-axis direction of a dispensing head moving on the stage and the X′-axis direction of a paste pattern to be formed on the substrate are deviated from each other by a predetermined angle θ. A reference point on a paste pattern which is initially input, i.e., an initial reference point, and a reference point at which the paste pattern is to be dispensed on the substrate, i.e., a last reference point, are different in position from each other.

Conventionally, the paste dispenser uses a θ-axis driver to match the X′-axis direction and Y′-axis direction of the paste pattern to be formed on the substrate with the X-axis direction of the nozzle and the Y-axis direction of the substrate, respectively, and forms the paste pattern on the substrate. That is, the conventional paste dispenser moves only the stage in the Y-axis direction to dispense the paste when a linear part of the paste pattern extending in the Y-axis direction is formed, and moves only the head unit in the X-axis direction to dispense the paste when a linear part of the paste pattern extending in the X-axis direction is formed.

However, the paste dispenser according to the present invention forms the paste pattern without correcting the initial position of the substrate that is mounted on the stage.

A step of forming the paste pattern will be described with reference to FIG. 8, in which the initial reference point and the last reference point are equal to each other and the substrate is deviated from a reference position by a predetermined angle.

When the substrate is mounted on the stage, the paste dispenser moves the column in the Y-axis, and acquires position information of the substrate by means of the position sensor mounted on the column (S30).

In order to acquire the position information of the substrate, the paste dispenser moves the column having the position sensor mounted thereon to a position at which an alignment mark can be detected. The paste dispenser takes a picture of the alignment mark by means of the position sensor.

The controller of the paste dispenser calculates a change in position of the substrate that corresponds to a deviation of the substrate from a reference position at which the substrate is to be located, on the basis of position data of the alignment mark. That is, the controller calculates the deviated angle of the substrate based on a change in position of the alignment mark.

A data processor 73 included in the controller automatically corrects the position data concerning the paste pattern that is initially input (thereinafter referred to as ‘initial pattern data’) (S40). That is, the data processor 73 corrects the initial pattern data based on the deviated angle of the substrate. Thereinafter, the corrected position data concerning the paste pattern is referred to as last pattern data. A user may directly input the position data concerning the paste pattern that is corrected based on the deviated angle.

Since the initial pattern data is based on the X-axis and Y-axis coordinates, the initial pattern data needs to be converted to the last pattern data to form the paste pattern on the X′-axis and Y′-axis coordinates. Thereinafter, the X-axis and Y-axis coordinate system is referred to as a first coordinate system, and the X′-axis and Y′-axis coordinate system is referred to as a second coordinate system.

For example, initial pattern data having a coordinate value of (5, 0) is converted to last pattern data having a coordinate value of (5 cos θ, 5 sin θ) by the data processor. The symbol θ implies the angle formed between the X′-axis direction, in which the paste pattern is to be formed, and the X-axis direction, in which the dispensing head is moved. The data processor is a microprocessor that is provided in the controller included in the paste dispenser. The data processor may be provided separately from the controller.

The controller controls the motor controller based on the last pattern data, and the motor controller controls the Y-axis driver, which moves the dispensing head in the Y-axis direction, to move the dispensing head on which the nozzle is mounted (S50).

That is, the controller moves the dispensing head in the Y-axis direction such that the X′-axis direction of the paste pattern to be formed and a virtual line 511 of the nozzles mounted on the dispensing heads are located on a straight line (see FIG. 8). The virtual line 511 is formed by connecting central points of nozzle outlets to one another. The paste pattern to be formed on the substrate 200 is depicted in a dotted line.

The paste dispenser moves the nozzle to a dispensing start point at which the paste is to be dispensed based on the last pattern data (S60). That is, the paste dispenser moves the column and the dispensing head to place the nozzle at a right position at which the paste is to be dispensed.

Finally, the paste dispenser forms the paste pattern based on the last pattern data (S70). In this case, the dispensing head of the paste dispenser moves to the X-axis direction, and the substrate moves to the Y-axis direction. However, the paste pattern actually formed on the substrate is formed to be deviated by a predetermined angle θ from the first coordinate system on which the substrate and the nozzle are moved.

That is, a linear part of the paste pattern has a gradient of 0 in the second coordinate system, but has a certain gradient in the first coordinate system. Thus, the substrate and the nozzle need to be moved at the same time to form the linear part of the paste pattern having a certain gradient in the first coordinate system.

Accordingly, the paste pattern is formed while the substrate and the nozzle are moved in the X-axis direction and Y-axis direction, respectively, at the same time at the deviated angle θ of the substrate.

In case only a single nozzle is used, the paste pattern can be formed while the substrate and the nozzle are moved in the X-axis direction and Y-axis direction, respectively, at the same time based on the last pattern data without moving the dispensing head in the Y-axis direction.

The paste dispenser according to the present invention forms the paste pattern without rotating the substrate about the θ-axis even though the initial reference point, i.e., the reference point on the paste pattern that is initially input, and the last reference point, i.e., the reference point of the paste pattern to be formed on the substrate, are different from each other and the substrate is deviated from the reference position by a certain angle.

In this case, the controller calculates a deviation of the substrate from the initial reference position based on the position information acquired from the position sensor. That is, the controller calculates a change in position between the initial reference point and the last reference point as well as the deviated angle of the substrate. The data processor converts the initial pattern data based on the deviation of the substrate.

In a case where the initial reference point has a coordinate value of (0,0), the last reference point has a coordinate value of (1,1), and the deviated angle of the substrate is θ, the initial pattern data having a coordinate of (5,0) is converted to the last pattern data having a coordinate of (1+5 cos θ,1+5 sin θ).

Next, the paste dispenser sets a position of the nozzle based on the converted pattern data, i.e., the last pattern data. That is, the paste dispenser moves the nozzle in the Y-axis direction such that the Y′-axis direction of the paste pattern and the virtual line, which is formed by connecting the central points of the nozzle outlets mounted on the dispensing heads to one another, are perpendicular to each other.

The paste dispenser moves the nozzle to a dispensing start point, at which the paste is initially dispensed, on the basis of the last pattern data. Finally, the paste dispenser forms the paste pattern while moving the nozzle and the substrate in the respective movement directions at the same time based on the last pattern data.

The paste dispenser according to the present invention has the following advantages.

According to the present invention, since the θ-axis driver needs not to be provided on the Y-axis stage carrier, it is possible to remove the vibration due to the θ-axis driver when the stage is moved in the Y-axis direction. In addition, it is possible to form the paste pattern on the substrate more accurately.

Moreover, since the θ-axis driver is not required, it is possible to reduce load imposed on the Y-axis stage carrier, thereby improving the response speed of the Y-axis stage carrier.

Moreover, the θ-axis driver for moving the stage having the substrate mounted thereon in the θ-axis direction to correct the position of the substrate before forming the paste pattern is not required, and a step of correcting the θ-axis is not required, thereby reducing the process time.

Moreover, since the θ-axis driver is not required, it is possible to reduce the volume of the paste dispenser and a production cost.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A paste dispenser comprising:
a dispensing head having a nozzle for dispensing paste mounted thereon; and
a stage having a substrate mounted thereon and moving relative to the dispensing head,
wherein the substrate mounted on the stage is moved without rotating the stage to form a paste pattern.

2. The paste dispenser according to claim 1, further comprising a position sensor acquiring position information of the substrate on the stage.

3. The paste dispenser according to claim 2, further comprising a controller calculating a change in position of the substrate corresponding to a deviation of the substrate from an initial reference position of the substrate on the basis of the position information of the substrate acquired by the position sensor.

4. The paste dispenser according to claim 3, wherein the change in position includes an angle formed between an X-axis movement direction of the dispensing head and an X′-axis direction of the paste pattern, and a change in position between an initial reference point on the paste pattern and a reference point of the paste pattern to be formed on the substrate mounted on the stage.

5. The paste dispenser according to claim 4, further comprising a data processor correcting initial position data of the paste pattern on the basis of the change in position of the substrate.

6. The paste dispenser according to claim 2, wherein when the paste is dispensed from the nozzle, the substrate and the nozzle are simultaneously moved in directions perpendicular to each other.

7. A paste dispenser comprising:
a stage having a substrate mounted thereon;
a dispensing head having mounted thereon a nozzle for dispensing paste on the substrate; and
a position sensor acquiring position information of the substrate on the stage,
wherein the dispensing head is moved without rotating the stage to set a position of the nozzle.

8. The paste dispenser according to claim 7, further comprising a Y-axis dispensing head carrier moving the nozzle to set the position of the nozzle based on the position information of the substrate.

9. The paste dispenser according to claim 8, wherein the Y-axis dispensing head carrier includes a servomotor and a motor shaft driven by the servomotor.

10. The paste dispenser according to claim 8, wherein an X′-axis direction of the paste pattern to be formed on the substrate and a virtual line formed by connecting central points of outlets of a plurality of nozzles each mounted on each of dispensing heads to one another are positioned in a straight line.

11. The paste dispenser according to claim 10, further comprising a data processor automatically correcting position data of the paste pattern formed on the substrate based on the position information of the substrate.

12. The paste dispenser according to claim 7, further comprising a controller controlling the substrate and the nozzle to be simultaneously moved in directions perpendicular to each other when the paste is dispensed from the nozzle.

13. A paste dispenser comprising:
a dispensing head having a nozzle for dispensing paste mounted thereon;
a column having the dispensing head mounted thereon and stopping operating when the paste is dispensed; and
a stage moving in a direction perpendicular to a movement direction of the dispensing head without rotating about the column.

14. The paste dispenser according to claim 13, further comprising a controller controlling the substrate and the nozzle to be simultaneously moved in directions perpendicular to each other when the paste is dispensed from the nozzle.

15. A method of controlling a paste dispenser, the method comprising:
putting a substrate on a stage;
acquiring position information of the substrate on the stage; and
setting a dispensing position of a nozzle by moving a dispensing head having the nozzle mounted thereon without rotating the stage.

16. The method according to claim 15, further comprising automatically correcting initial position data of a paste pattern on the basis of the position information of the substrate.

17. The method according to claim 16, wherein a step of acquiring position information of the substrate further comprises calculating a change in position of the substrate corresponding to a deviation of the substrate from an initial reference position of the substrate on the basis of the position information of the substrate.

18. The method according to claim 17, wherein a step of setting a dispensing position of a nozzle comprises moving dispensing heads such that a Y′-axis direction of the paste pattern to be formed on the substrate and a virtual line formed by connecting central points of outlets of a plurality of nozzles each mounted on each of the dispensing heads to one another are positioned in directions perpendicular to each other.

19. The method according to claim 15, further comprising forming the paste pattern while moving the nozzle in a direction perpendicular to a movement direction of the substrate at the same time when the substrate is moved.

20. The method according to claim 15, comprising forming a paste pattern while converting initial position data of the paste pattern based on the position information of the substrate and moving the nozzle and the substrate along individual movement directions at the same time on the basis of the converted position data.

21. A method of controlling a paste dispenser, the method comprising:
putting a substrate on a stage;
inputting position data of a paste pattern formed on the substrate;
acquiring position information of the substrate on the stage; and
correcting initial position data of the paste pattern on the basis of the position information of the substrate.

22. The method according to claim 21, further comprising forming the paste pattern while moving the substrate and a nozzle along individual movement directions at the same time on the basis of the corrected position data.

23. The method according to claim 22, further comprising moving a dispensing head mounted on a column to a dispensing start point of the paste pattern to be formed.

24. The method according to claim 21, wherein a step of acquiring position information of the substrate comprises:
moving a column having a position sensor mounted thereon to a position of an alignment mark; and
identifying the alignment mark by means of the position sensor.

25. The method according to claim 24, wherein a step of acquiring position information of the substrate further comprises calculating a change in position of the substrate corresponding to a deviation of the substrate from an initial reference position of the substrate on the basis of position data of the identified alignment mark.
